(19) United States
(12) Patent Application Publication
(10) Pub. No.: US 2004/0004808 A1
(43) Pub. Date: Jan. 8, 2004

(54) Electronic control device

(75) Inventors: Takao Tsunooka, Kariya-shi (JP); Matsuhisa Tsuruta, Toyota-shi (JP); Hiroyuki Masubuchi, Kariya-shi (JP); Takeshi Ikeyama, Nagoya-shi (JP)

Correspondence Address: BURNS DOANE SWECKER & MATHIS L L P, POST OFFICE BOX 1404, ALEXANDRIA, VA, 22313-1404, US

(73) Assignee: AISIN SEIKI KABUSHIKI KAISHA

(21) Appl. No.: 10/420,825

(22) Filed: Apr. 23, 2003

(30) Foreign Application Priority Data
Apr. 23, 2002 (JP) 2002-121006

(51) Int. Cl. H05K 5/00

(52) U.S. Cl. 361/679

(57) ABSTRACT

An electronic control device includes a board on which electronic parts are provided and a case member accommodating the board and plural cylindrical coils. The plural cylindrical coils have terminals electrically connected to the board by soldering. In the device, an intermediate wall dividing the board from the plural cylindrical coils is formed on the case member, and a stress absorbing means for preventing generation of a solder break on each connection part between the terminals and the board by thermal load is provided between the board and the intermediate wall.

### CROSS REFERENCE TO RELATED APPLICATIONS

The application is based on and claims priority under 35 U.S.C. § 119 with respect to a Japanese Patent Application 2002-121006, filed on Apr. 23, 2002, the entire content of which is incorporated herein by reference.

### FIELD OF THE INVENTION

This invention generally relates to an electronic control device, and more particularly, this invention pertains to an electronic control device for operating and controlling a pressure control device such as an ABS actuator of a vehicle.

### BACKGROUND OF THE INVENTION

For example, an electronic control device shown in FIG. 3 is known. The device is used to operate and control a pressure control device of a vehicle including a solenoid valve. This electronic control device 120 has a board 124 on which electronic parts (not shown) are provided and a case member 121 which houses plural cylindrical coils 125. The electronic control device is assembled to a pressure control device 110. An intermediate wall 122a is formed on the case member 121 made of a resin material and divides the board 124 from the coils 125. Terminals 126 of the coils 125 are inserted through holes provided on the intermediate wall 122a and electrically connected to the board 124 by soldering.

The known electronic control device, above described, is generally mounted within an engine compartment of the vehicle. Consequently, the device is affected by heat generated by the engine, and the case member 121 may be deformed and particularly, soldering parts on connection parts 128 between the terminals 126 and the board 124 may be broken by a difference in a coefficient of thermal expansion between a resin made board and metal coil terminals. To prevent a solder break, as shown in FIG. 3, a stress absorbing means 126a is provided in the electronic control device and made of the terminals 126 formed with a bended shape for reducing stress generated by thermal load on each connection part 128.

However, the stress absorbing means 126a provided in the electronic control device causes enlargement of a device size in axial direction with respect to the terminals 126 (an upward and a downward direction in FIG. 3). The foregoing device cannot satisfy the requirement for downsizing which can eventually reduce vehicle weight and reduce required space for the device in a limited engine compartment.

The present invention therefore seeks to provide an improved electronic control device capable of achieving a downsized electronic control device as well as of stress absorbing for reducing stress which may cause a solder break on connection part between a terminal and a board due to thermal load.

### SUMMARY OF THE INVENTION

According to an aspect of the present invention, an electronic control device includes a board on which electronic parts are provided and a case member accommodating the board and plural cylindrical coils. The plural cylindrical coils have terminals electrically connected to the board by soldering. In the device, an intermediate wall dividing the board from the plural cylindrical coils is formed on the case member, and a stress absorbing means for preventing generation of a solder break on each connection part between the terminals and the board by thermal load is provided between the board and the intermediate wall.

According to another aspect of the present invention, the case member is made of a resin material, and the plural cylindrical coils are embedded in the case member by integral molding. The stress absorbing means is formed by bending the terminals.

### BRIEF DESCRIPTION OF THE DRAWING FIGURES

The foregoing and additional features and characteristics of the present invention will become more apparent from the following detailed description considered with reference to the accompanying drawing figures wherein:

FIG. 1 is a cross sectional view of a main part of an electronic control device according to an embodiment of the present invention;

FIG. 2 is a cross sectional view taken along the line A-A of FIG. 1; and

FIG. 3 is a cross sectional view of a known electronic control device.

### DETAILED DESCRIPTION OF THE INVENTION

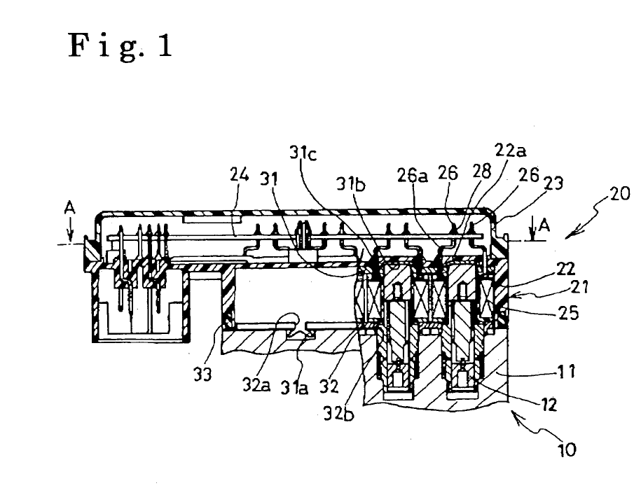

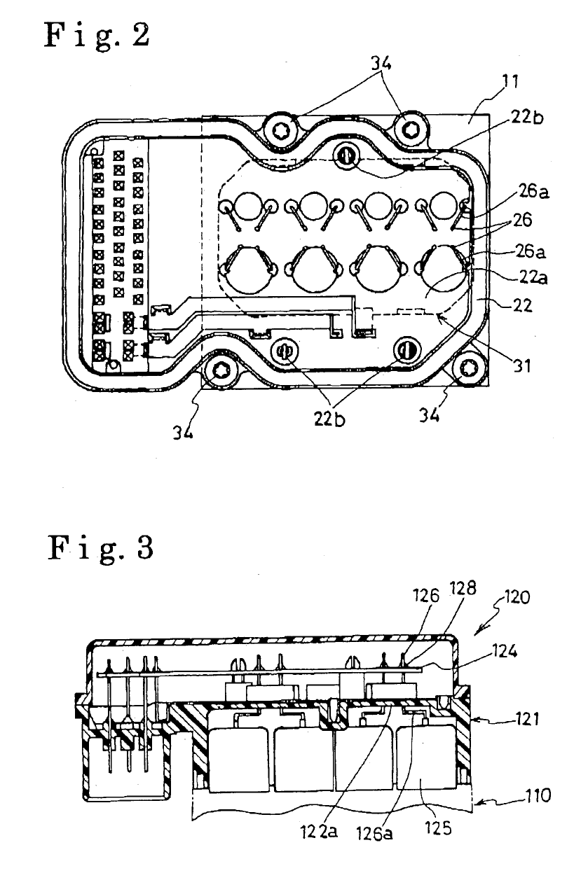

FIG. 1 and FIG. 2 show an electronic control device according to an embodiment of the present invention. In the embodiment, an electronic control device 20 is assembled to a pressure control device 10 for controlling brake fluid pressure operating an ABS actuator of a vehicle. The pressure control device 10 and the electronic control device 20 are generally mounted within an engine compartment of the vehicle.

A motor driven hydraulic pump (not shown) and a hydraulic circuit (not shown) are provided within the pressure control device 10. A housing 11 of the pressure control device 10 is made of aluminum alloy, and each one part of eight solenoid valves 12 is accommodated in the housing 11. The solenoid valves 12 are, for example, composed of four pairs of 2 WAY-valves having two valves (a normal-open valve and a normal-closed valve). All the solenoid valves 12 shown in FIG. 1 are the normal-closed valves. The electronic control device 20 has a board 24 where electronic parts (not shown) for controlling the solenoid valves 12 are provided and a case member 21. The case member 21 houses the board 24, eight cylindrical coils 25 corresponding to the solenoid valves 12, and a pair of yokes (a primary yoke 31 and a secondary yoke 32).

The case member 21 is composed of a case body 22 and a case cover 23 which are made of a resin material, and the case cover 23 is tightly connected to the case body 22 by welding. The case body 22 is fixed to the housing 11 via packing 33 by four bolts 34. Thus, an inner part of the case member 21 is sealed against the atmosphere.

An intermediate wall 22a and a holding part 22b are integrally formed on the case body 22. The intermediate wall 22a divides the board 24 from the coils 25. The holding part 22b has a function, what we call snap fit, so the board 24 can be easily assembled and tightly fixed without using other fixing means.

The coils 25 are formed by bobbins made of a resin material and wires coiled around the bobbins, and each end of the wires is connected to terminals 26. The terminals 26 extend upward (a direction in FIG. 1), and the coils 25 sides of the terminals 26 are partially covered by a resin material.

The primary yoke 31 is made of a magnetic material and has a reverse U-shape opening downward (a direction in FIG. 1). A recess part 31b is formed on a bottom face of the primary yoke 31 and faces to upper ends of the solenoid valves 12. Holes 31c are also formed on the bottom face of the primary yoke 31, and the terminals 26 are inserted through the holes 31. Fixing parts 31 a having a pair of clamps are provided at each end part of the primary yoke 31.

The secondary yoke 32 is also made of the magnetic material and has a plate shape. Cylindrical parts 32b perpendicular to the plate shaped body part are formed on the secondary yoke 32. Each end part of the secondary yoke 32 has groove parts 32a for receiving the foregoing fixing parts 31a.

After the coils 25 are assembled to the primary yoke 31 and the secondary yoke 32, the fixing parts 31 a formed on the primary yoke 31 are accommodated in the groove parts 32a, and then each pair of clamps is opened so that the primary yoke 31 is tightly fixed to the secondary yoke 32. The pair of yokes 31 and 32 to which the coils 25 are assembled is embedded in the case body 22 by integral molding. The primary yoke 31 closely contacts with the intermediate wall 22a, and the terminals 26 project from the intermediate wall 22a.

In the embodiment of the present invention, two terminals 26 per one coil 25, or total sixteen terminals 26 are provided (numerals are expediently indicated only for two terminals in FIG. 2), and each end of the terminals 26 is electrically connected to the board 24 by soldering. Each terminal 26, as shown in FIG. 1 and FIG. 2, has a stress absorbing means 26a. Each stress absorbing means 26a has two L-shaped parts between the board 24 and the intermediate wall 22a, and each L-shaped part includes two bended parts with an angle of approximately 90°.

The electronic control device 20 is mounted in the engine compartment of the vehicle. Consequently, the device is affected by heat generated by the engine, and the case member 21 may be deformed and particularly, soldering parts on connection parts 28 between the terminals 26 and the board 24 may be broken by a difference in a coefficient of thermal expansion between a resin made board and metal terminals. Each stress absorbing means 26a can reduce stress generated on each connection part 28 by thermal load and prevent a solder break.

Operation of the above described electronic control device according to the present invention is not different from that of the known conventional electronic control device. Based on indication from a controller (not shown) for controlling the device, the coils 25 are energized by power supply via the terminals 26, and then the solenoid valves 12 are operated and controlled.

In the electronic control device according to the present invention, each stress absorbing means 26a is provided between the board 24 and the intermediate wall 22a, clearance between the coils 25 and the intermediate wall 22a can be minimized, and the solder break on each connection part 28 between each terminal 26 and the board 24 by the thermal load also can be prevented. Consequently, the electronic control device 20 can be downsized, so flexibility of mounting space required for the device in the limited engine compartment of the vehicle can be improved. The downsized case member 21 can further contribute to cost and weight reduction of the resin material.

The case body 22 of the case member 21 is made of the resin material. The coils 25, the primary yoke 31, and the secondary yoke 32 are embedded in the case body 22 by the integral molding, and the clearance between the coils 25 and the intermediate wall 22a can be minimized. Additionally, the coils 25 are integrally assembled to the case member 21, the coils 25 need not to be assembled to the case member 21 one by one, and improvement in assembling can be achieved.

Further, each stress absorbing means 26a can be provided by an easy and low-cost method for forming each terminal 26 with the bended shape.

In the foregoing embodiment, each stress absorbing means 26a has two L-shaped parts with the angle of approximately 90°. Any shape different from the shape of this embodiment and capable of absorbing stress can be applied to a stress absorbing means according to the present invention.

As described above, according to the present invention, an electronic control device, which can be downsized as well as absorbing stress for preventing a solder break on a connection part between a terminal and a board by thermal load, can be achieved.

The principles, preferred embodiments and mode of operation of the present invention have been described in the foregoing specification. However, the invention which is intended to be protected is not to be construed as limited to the particular embodiments disclosed. Further, the embodiments described herein is to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What we claim is:

1. An electronic control device comprising:
a board on which electronic parts are provided; and
a case member accommodating the board and plural cylindrical coils, the plural cylindrical coils having terminals electrically connected to the board by soldering, wherein an intermediate wall dividing the board from the plural cylindrical coils is formed on the case member, and a stress absorbing means for preventing generation of a solder break on each connection part between the terminals and the board by thermal load is provided between the board and the intermediate wall.

2. An electronic control device according to claim 1, wherein the case member is made of a resin material, and the plural cylindrical coils are embedded in the case member by integral molding.

3. An electronic control device according to claim 1, wherein the stress absorbing means is formed by bending the terminals.

4. An electronic control device comprising:
a board on which electronic parts are provided;
a case member accommodating the board and plural cylindrical coils having terminals electrically connected to the board by soldering;
an intermediate wall dividing the board from the plural cylindrical coils and formed on the case member; and
a stress absorbing means for preventing generation of a solder break on each connection part between the terminals and the board by thermal load, the stress absorbing means being provided between the board and the intermediate wall.

5. An electronic control device comprising:
a board on which electronic parts are provided; and
a case member accommodating the board and plural cylindrical coils, the plural cylindrical coils having metal terminals electrically connected to the board by soldering, wherein an intermediate wall dividing the board from the plural cylindrical coils is formed on the case member, and a stress absorbing means for preventing generation of a solder break on each connection part between the metal terminals and the board by thermal load is provided between the board and the intermediate wall and made of the metal terminals.

6. An electronic control device according to claim 5, wherein the stress absorbing means has several bended parts capable of preventing the solder break.

7. An electronic control device according to claim 5, wherein the metal terminals are made of a thin metal plate.

8. An electronic control device according to claim 6, wherein the metal terminals are made of a thin metal plate.

9. An electronic control device comprising:
a board on which electronic parts are provided; and
a case member accommodating the board and plural cylindrical coils, the plural cylindrical coils having terminals electrically connected to the board by soldering, wherein an intermediate wall dividing the board from the plural cylindrical coils is formed on the case member, and a stress absorbing means for preventing generation of a solder break on each connection part between the terminals and the board by thermal load is provided between the board and the intermediate wall and made of the terminals.
